(19) United States
(12) Patent Application Publication
(10) Pub. No.: US 2025/0340985 A1
(43) Pub. Date: Nov. 6, 2025

(54) SUBSTRATE PROCESSING METHOD

(71) Applicant: Tokyo Electron Limited, Tokyo (JP)

(72) Inventors: Yoshihiro KATO, Yamanashi (JP); Kazuki GOTO, Yamanashi (JP); Shuichiro SAKAI, Yamanashi (JP)

(21) Appl. No.: 19/272,175

(22) Filed: Jul. 17, 2025

Related U.S. Application Data
(63) Continuation of application No. PCT/JP2024/002939, filed on Jan. 30, 2024.

(30) Foreign Application Priority Data
Feb. 6, 2023 (JP) 2023-016384

(51) Int. Cl. C23C 16/455; C23C 16/30; C23C 16/36

(52) U.S. Cl. CPC C23C 16/4554; C23C 16/30; C23C 16/36; C23C 16/45553

(57) ABSTRACT

A substrate processing method includes: i) executing a cycle of i-i) supplying a nitrogen-containing gas to a substrate having a recess and i-ii) supplying a raw material gas including silicon and carbon to the substrate, the cycle being executed one or more times to form a film including at least silicon, carbon, and nitrogen, and i-i) and i-ii) being performed in the order as mentioned; and ii) exposing the substrate on which the film is formed in i) to plasma of a hydrogen-containing gas to modify the film.

### CROSS-REFERENCE TO RELATED APPLICATIONS

The present application is a continuation application of International Application No. PCT/JP2024/002939 filed on Jan. 30, 2024, which is based on and claims priority to Japanese Patent Application No. 2023-016384 filed on Feb. 6, 2023, the contents of which are incorporated herein by reference.

### BACKGROUND

### 1. Field of the Invention

The present disclosure relates to substrate processing methods.

### 2. Description of the Related Art

A film formation method is disclosed in Japanese Unexamined Patent Application Publication No. 2020-150206. The disclosed film formation method includes a first step of forming a film including silicon, carbon, and nitrogen on a substrate, and a second step including a step of oxidizing the film using an oxidizing agent including a hydroxyl group, and after the step of oxidizing, a step of supplying nitriding gas to the substrate.

A substrate processing method is disclosed in Japanese Unexamined Patent Application Publication No. 2022-65560. The disclosed substrate processing method includes a step of executing a cycle that includes an operation of supplying a raw material gas including silicon, carbon, and halogen to a substrate, and an operation of supplying a first reaction gas to the substrate at least once to form a film on the substrate, and a step of exposing the substrate to plasma of a hydrogen-containing gas to modify the film formed on the substrate.

### SUMMARY

According to one aspect, a substrate processing method includes: i) executing a cycle of i-i) supplying a nitrogen-containing gas to a substrate having a recess and i-ii) supplying a raw material gas including silicon and carbon to the substrate, the cycle being executed one or more times to form a film including at least silicon, carbon, and nitrogen, and i-i) and i-ii) being performed in the order as mentioned; and ii) exposing the substrate on which the film is formed in i) to plasma of a hydrogen-containing gas to modify the film.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is an example of a schematic view illustrating a configuration example of a substrate processing apparatus;

FIG. 2 is a flowchart illustrating one example of a substrate processing method according to the present embodiment;

FIG. 3 is a time chart illustrating one example of the substrate processing method according to the present embodiment;

FIG. 4 is a flowchart illustrating another example of the substrate processing method according to the present embodiment;

FIG. 5 is a time chart illustrating another example of the substrate processing method according to the present embodiment;

FIG. 6A is an example of a time chart of an ALD cycle for forming an insulation film;

FIG. 6B is an example of a time chart of an ALD cycle for forming an insulation film;

FIG. 6C is an example of a time chart of an ALD cycle for forming an insulation film;

FIG. 6D is an example of a time chart of an ALD cycle for forming an insulation film;

FIG. 6E is an example of a time chart of an ALD cycle for forming an insulation film;

FIG. 6F is an example of a time chart of an ALD cycle for forming an insulation film;

FIG. 6G is an example of a time chart of an ALD cycle for forming an insulation film;

FIG. 7 is an example of a graph presenting compositions and densities of the formed insulation films;

FIG. 8 is an example of a graph presenting wet etching resistance of the formed insulation films;

FIG. 9 is an example of a schematic diagram illustrating an insulation film formed in a trench;

FIG. 10 is an example of a graph presenting etching amounts of the insulation films each of which is formed on a side wall of the trench;

FIG. 11 is an example of a graph presenting dielectric constants of insulation films;

FIG. 12 is an example of a graph presenting compositions and densities of formed insulation films;

FIG. 13 is an example of a graph presenting wet etching resistance of the formed insulation films; and

FIG. 14 is an example of a graph presenting dielectric constants of insulation films.

### DETAILED DESCRIPTION

Embodiments for carrying out the present disclosure will be described with reference to drawings hereinafter. In the drawings, the same constituent component is denoted by the same reference numeral, and redundant description may be omitted.

### [Substrate Processing Apparatus]

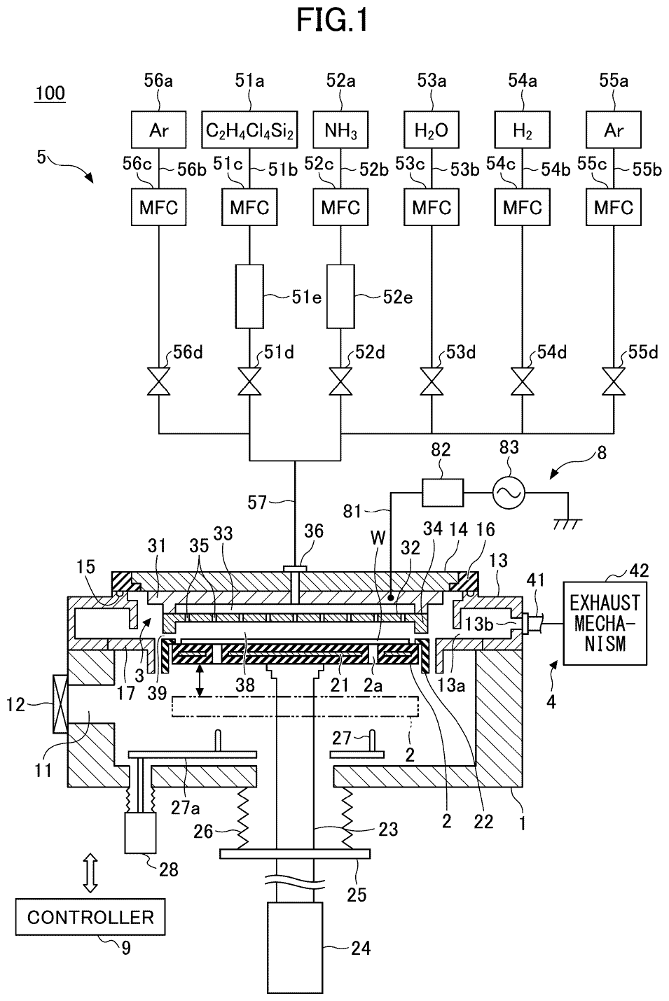

The substrate processing apparatus 100 according to the present embodiment will be described with reference to FIG. 1. FIG. 1 is an example of a schematic view illustrating a configuration example of the substrate processing apparatus 100. The substrate processing apparatus 100 is a device that is configured to form an insulation film on a wafer (substrate) W in a processing chamber in a vacuumed state by atomic layer deposition (ALD). The insulation film formed on the wafer W is a film including at least silicon (Si), carbon (C), and nitrogen (N), for example, a SiCN film. Moreover, the insulation film formed on the wafer W may be a film that further includes oxygen (O), for example, a SiOCN film.

As illustrated in FIG. 1, the substrate processing apparatus 100 includes a processing chamber 1, a stage 2, a showerhead 3, an exhaust 4, a gas supply mechanism 5, a radio frequency (RF)-power supply 8, and a controller 9.

The processing chamber 1 is formed of a metal, such as aluminum or the like, and has substantially a cylindrical shape. The processing chamber 1 houses a wafer W. A loading port 11 through which the wafer W is transported in and out is formed in a side wall of the processing chamber 1. The loading port 11 is opened and closed by a gate valve 12. An annular exhaust duct 13 having a rectangular cross-sectional shape is disposed above a main body of the processing chamber 1. A slit 13a is formed along an inner circumferential surface of the exhaust duct 13. An exhaust port 13b is formed in an outer wall of the exhaust duct 13. A ceiling wall 14 is disposed on an upper surface of the exhaust duct 13 to cover an upper opening of the processing chamber 1 via an insulating member 16. A space between the exhaust duct 13 and the insulating member 16 is airtightly sealed by a seal ring 15. A partition member 17 partitions the interior of the processing chamber 1 into an upper side and a lower side when the stage 2 (and a cover member 22) is lifted to a below-described processing position.

The stage 2 horizontally supports the wafer W in the processing chamber 1. The stage 2 is formed in a disc shape having a size corresponding to the wafer W, and is supported by a support member 23. The stage 2 is formed of a ceramic material, such as aluminum nitride (AlN) or the like, or a metal material, such as aluminum, a nickel alloy, or the like, and a heater 21 for heating the wafer W is embedded in the stage 2. A heater power supply (not illustrated) supplies electricity to the heater 21 to generate heat. The temperature of the wafer W is regulated at a set temperature by controlling an output of the heater 21 according to a temperature signal of a thermocouple (not illustrated) disposed in the vicinity of an upper surface of the stage 2. A cover member 22 formed of a ceramic, such as alumina or the like, is disposed above the stage 2 to cover an outer peripheral region of the upper surface of the stage 2, and a side surface of the stage 2.

A support member 23 is disposed on a bottom surface of the stage 2, and supports the stage 2. The support member 23 extends from a center of the bottom surface of the stage 2 to the bottom of the processing chamber 1 through a hole formed in a bottom wall of the processing chamber 1, and a lower end of the support member 23 is coupled to a lifting mechanism 24. The stage 2 is lifted up and lowered down, by the lifting mechanism 24, between the processing position and the loading position illustrated in FIG. 1. The loading position is indicated with a double-dashed chain line, and is a position where the wafer W can be transported in and out. A flange 25 is attached to the support member 23 below the processing chamber 1. A bellows 26 is disposed between the bottom surface of the processing chamber 1 and the flange 25. The bellows 26 partitions the inner atmosphere of the processing chamber 1 off from the outside air, and expands and contracts according to the lifting and lowering movements of the stage 2.

In the vicinity of the bottom surface of the processing chamber 1, three (only two are illustrated) wafer support pins 27 are disposed to be projected upward from a lifting plate 27a. The wafer support pins 27 are lifted up and lowered down with the lifting plate 27a by a lifting mechanism 28 disposed below the processing chamber 1. The wafer support pins 27 are inserted through holes 2a formed in the stage 2 in the loading position to be projected from and pulled down from the upper surface of the stage 2. By lifting and lowering the wafer support pins 27, the wafer W is transported between a transfer mechanism (not illustrated) and the stage 2.

The showerhead 3 is configured to supply a processing gas into the processing chamber 1 in the form of a shower. The showerhead 3 is formed of a metal, disposed to face the stage 2, and has substantially the same diameter as a diameter of the stage 2. The showerhead 3 includes a main body 31 and a shower plate 32. The main body 31 is fixed onto the ceiling wall 14 of the processing chamber 1. The shower plate 32 is connected to the bottom of the main body 31. A gas diffusion space 33 is created between the main body 31 and the shower plate 32. A gas inlet hole 36 is provided to the gas diffusion space 33, where the gas inlet hole 36 penetrates through the ceiling wall 14 of the processing chamber 1 and a center of the main body 31. An annular projection 34 projecting downward is formed on the peripheral edge of the shower plate 32. Gas discharge holes 35 are formed in a flat portion located on an inner side of the annular projection 34. In a state where the stage 2 is in the processing position, a processing space 38 is created between the stage 2 and the shower plate 32, and an annular gap 39 is formed by bringing the upper surface of the cover member 22 close to the annular projection 34.

The exhaust 4 exhausts the inner atmosphere of the processing chamber 1. The exhaust 4 includes an exhaust pipe 41 connected to an exhaust port 13b, and an exhaust mechanism 42 connected to the exhaust pipe 41. The exhaust mechanism 42 includes a vacuum pump, a pressure control valve, and the like. During processing, a gas inside the processing chamber 1 passes through the slit 13a to reach the exhaust duct 13, and the gas is exhausted from the exhaust duct 13 by the exhaust mechanism 42 through the exhaust pipe 41.

The gas supply mechanism 5 is configured to supply processing gases into a processing chamber 1. The gas supply mechanism 5 includes a precursor gas source 51a, a first reaction gas source 52a, a second reaction gas source 53a, and a hydrogen gas source 54a.

The precursor gas source 51a supplies a precursor gas (raw material gas) to the processing chamber 1 through a gas supply line 51b. As the precursor gas, a silicon precursor including at least a halogen group is used. Moreover, as the precursor gas, a precursor including silicon, carbon, and halogen is used. Further, as the precursor gas, a silicon precursor including at least a halogen group and an alkyl group is used. The halogen in the silicon precursor may include, for example, Cl, F, Br, I, or any combination of the foregoing. As the precursor gas, for example, a gas selected from the group consisting of 1,1,3,3-tetrachloro-1,3-disilacyclobutane (C₂H₄Cl₄Si₂), 1,1,3,3-tetrachloro-1,3-disilapropane (CH₄Cl₄Si₂), and 1,1,1,3,3,3-hexachloro-2-methyl-1,3-disilapropane (C₂H₄Cl₆Si₂), which are represented by the following structural formulae, can be used. In the example illustrated in FIG. 1, C₂H₄Cl₄Si₂ is used as the precursor gas (raw material gas).

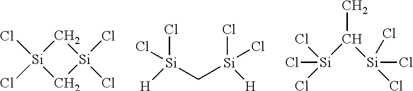

A flow-rate regulator 51c, a reservoir tank 51e, and a valve 51d are provided to the gas supply line 51b in this order from the upstream side. The downstream side of the gas supply line 51b relative to the valve 51d is coupled to a gas inlet hole 36 via gas supply line 57. The precursor gas supplied from the precursor gas source 51a is temporarily retained in the reservoir tank 51e before being supplied to the processing chamber 1, and is pressurized at a set pressure in the reservoir tank 51e, followed by being supplied to the processing chamber 1. The supply of the precursor gas from the reservoir tank 51e to the processing chamber 1 and the stop of the supply are performed by opening and closing the valve 51d. Since the precursor gas is temporarily retained in the reservoir tank 51e as described above, the precursor gas can be stably supplied to the processing chamber 1 at a relatively high flow rate.

The first reaction gas source 52a supplies a first reaction gas to the processing chamber 1 through the gas supply line 52b. As the first reaction gas, a nitriding gas (nitrogen-containing gas) is used. As the nitriding gas, for example, a gas selected from the group consisting of ammonia NH₃, diazene N₂H₂, hydrazine N₂H₄, and an organic hydrazine compound can be used. Moreover, as the organic hydrazine compound, for example, monomethyl hydrazine CH₃(NH)NH₂ or the like can be used. In the example illustrated in FIG. 1, NH₃ is used as the first reaction gas (nitriding gas).

A flow-rate regulator 52c, a reservoir tank 52e, and a valve 52d are provided to the gas supply line 52b from the upstream side. The downstream side of the gas supply line 52b relative to the valve 52d is coupled to a gas inlet hole 36 via the gas supply line 57. The nitrogen-containing gas supplied from the first reaction gas source 52a is temporarily retained in the reservoir tank 52e before being supplied to the processing chamber 1, and pressurized at a set pressure in the reservoir tank 52e, followed by being supplied to the processing chamber 1. The supply of the precursor gas from the reservoir tank 52e to the processing chamber 1 and the stop of supply are performed by opening and closing the valve 51d. Since the nitrogen-containing gas is temporarily retained in the reservoir tank 52e, the nitrogen-containing gas can be stably supplied to the processing chamber 1 at a relatively high flow rate.

The second reaction gas source 53a supplies a second reaction gas to the processing chamber 1 through the gas supply line 53b. As the second reaction gas, an oxidizing gas (oxygen-containing gas) is used. As the oxidizing gas, for example, a gas selected from the group consisting of H₂O, H₂O₂, D₂O, O₂, O₃, and alcohol can be used. Moreover, as the alcohol, for example, isopropyl alcohol (IPA) or the like can be used. In the example illustrated in FIG. 1, H₂O is used as the second reaction gas (oxidizing gas).

A flow-rate regulator 53c and a valve 53d are provided to the gas supply line 53b from the upstream side. The downstream side of the gas supply line 53b relative to the valve 53d is coupled to a gas inlet hole 36 via the gas supply line 57. The second reaction gas supplied from the second reaction gas source 53a is supplied into the processing chamber 1. The supply of the second reaction gas from the second reaction gas source 53a to the processing chamber 1 and the stop of supply are performed by opening and closing the valve 53d.

The hydrogen gas source 54a supplies a hydrogen-containing gas to the processing chamber 1 through the gas supply line 54b. As the hydrogen-containing gas, for example, a H₂ gas can be used. In the example illustrated in FIG. 1, H₂ is used as the hydrogen-containing gas.

A flow-rate regulator 54c and a valve 54d are provided to the gas supply line 54b. The downstream side of the gas supply line 54b relative to the valve 54d is coupled to the gas inlet hole 36 via the gas supply line 57. The hydrogen-containing gas supplied from the hydrogen gas source 54a is supplied into the processing chamber 1. The supply of the hydrogen-containing gas from the hydrogen gas source 54a to the processing chamber 1 and the stop of supply are performed by opening and closing the valve 54d.

The carrier gas/purge gas sources 55a and 56a supply an inert gas serving as a carrier gas/purge gas to the processing chamber 1 through the gas supply lines 55b and 56b, respectively. As the carrier gas/purge gas, for example, a gas selected from the group consisting of Ar, N₂, and He can be used. In the example illustrated in FIG. 1, Ar is used as the carrier gas/purge gas.

Flow-rate regulators 55c and 56c and valves 55d and 56d are respectively provided to the gas supply lines 55b and 56b from the upstream side. The downstream side of the gas supply line 55b or 56b relative to the valve 55d or 56d is coupled to the gas inlet hole 36 via the gas supply line 57. The carrier gas/purge gas supplied from the carrier gas/purge gas source 55a or 56a is supplied into the processing chamber 1. The supply of the carrier gas/purge gas from the carrier gas/purge gas source 55a or 56a to the processing chamber 1 and the stop of supply are performed by opening and closing the valve 55d or 56d.

Moreover, the substrate processing apparatus 100 is a capacitively coupled plasma device, in which the stage 2 serves as a lower electrode, and the showerhead 3 serves as an upper electrode. The stage 2 serving as the lower electrode may be grounded via a capacitor (not illustrated).

The RF-power supply 8 supplies high-frequency power (may be referred to as “RF power” hereinafter) to the showerhead 3 serving as an upper electrode. The RF-power supply 8 includes a power supply line 81, an impedance matching device 82, and an RF-power source 83. The RF-power source 83 is a power source that generates RF power. The RF-power frequencies are suitable for generation of plasma. The frequencies of the RF power are, for example, in a range of 450 KHz to 100 MHz. The RF-power source 83 is coupled to the main body 31 of the showerhead 3 via the impedance matching device 82 and the power supply line 81. The impedance matching device 82 includes a circuit for matching lead impedance (upper electrode) with output impedance of the RF-power source 83. The RF-power supply 8 is explained through an embodiment where the RF-power supply 8 applies RF power to the showerhead 3 serving as the upper electrode, but the RF-power supply 8 is not limited to the above-described embodiment. The RF-power supply 8 may be configured to apply RF power to the stage 2 serving as a lower electrode.

The controller 9 is, for example, a computer, and includes a central processing unit (CPU), a random access memory (RAM), a read only memory (ROM), an auxiliary storage device, and the like. The CPU operates based on one or more programs stored in the ROM or auxiliary storage device, and controls operations of the substrate processing apparatus 100. The controller 9 may be provided inside or outside the substrate processing apparatus 100. When the controller 9 is provided outside the substrate processing apparatus 100, the controller 9 can control the substrate processing apparatus 100 by a communication system, such as a wired communication system, a wireless communication system, or the like.

### [Film Formation Process of Insulation Film Using Substrate Processing Apparatus]

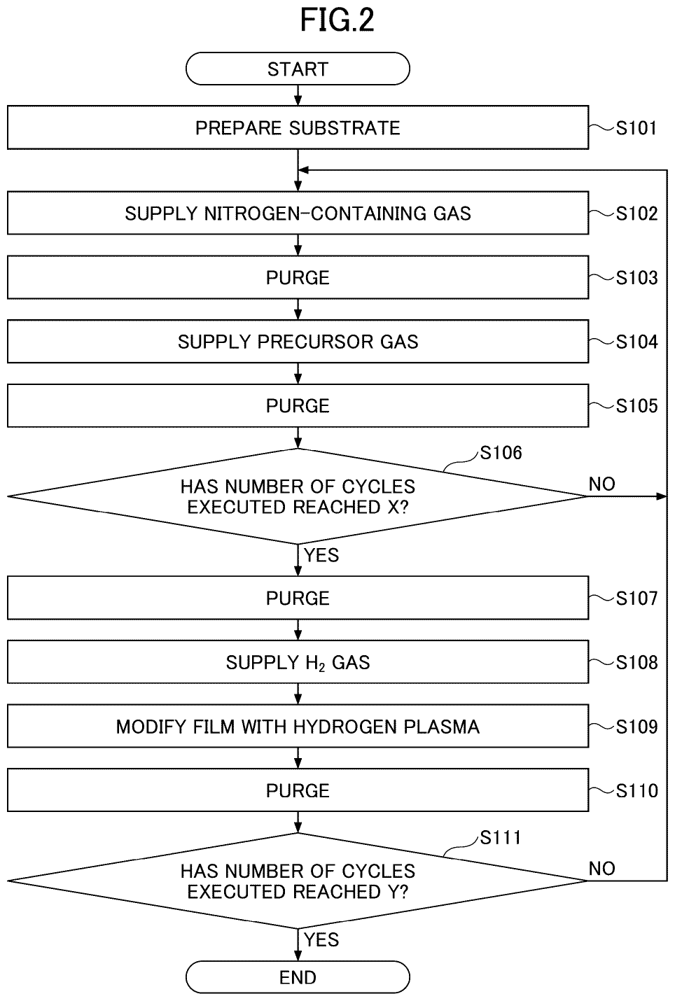

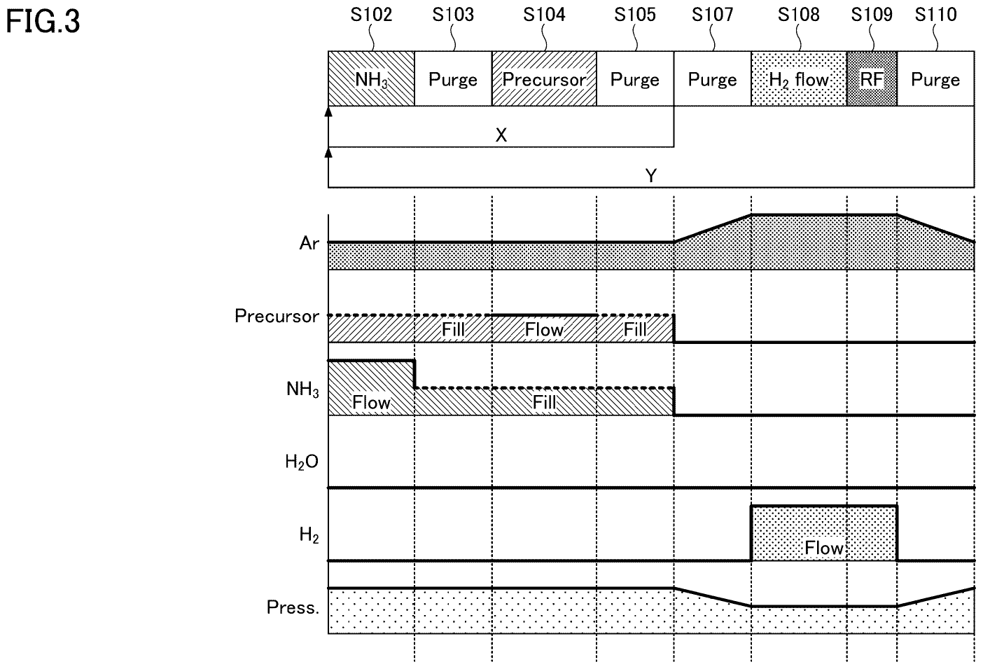

Next, an example of an operation of the substrate processing apparatus 100 will be described with reference to FIGS. 2 and 3. FIG. 2 is a flowchart illustrating one example of the substrate processing method according to the present embodiment. FIG. 3 is a time chart illustrating one example of the substrate processing method according to the present embodiment. In FIGS. 2 and 3, the example where the substrate processing apparatus 100 forms, as an insulation film, a SiCN film on a wafer W is described.

In FIG. 3, “Ar” represents one example of a flow rate of an Ar gas; “Precursor” represents one example of a flow rate of a precursor gas; “NH₃” represents one example of a flow rate of a NH₃ gas serving as a nitrogen-containing gas; “H₂O” represents one example of a flow rate of a H₂O gas serving as an oxygen-containing gas; “H₂” represents one example of a flow rate of a H₂ gas serving as a hydrogen-containing gas; and “Press.” represents one example of the pressure in a processing space 38.

At step S101, a wafer W is prepared. First, the wafer W is loaded into the processing chamber 1 of the substrate processing apparatus 100 illustrated in FIG. 1. Specifically, the gate valve 12 is opened in a state in which the stage 2 is lowered to a loading position. Subsequently, the wafer W is loaded into the processing chamber 1 through a loading port 11 by a transfer arm (not illustrated), and is placed on the stage 2 heated at a set temperature (e.g., 200° C. to 500° C.) by a heater 21. Subsequently, the stage 2 is lifted to the processing position, and the inner atmosphere of the processing chamber 1 is depressurized by the exhaust mechanism 42 to a set degree of vacuum. After depressurizing, the controller 9 performs control of opening the valves 55d and 56d, thereby supplying an Ar gas from the carrier gas/purge gas sources 55a and 56a. Thus, the inner atmosphere of the processing chamber 1 is stabilized at a set pressure.

Next, the controller 9 performs a first step (S102 to S106) of forming a SiCN film on the wafer W.

At step S102, a nitrogen-containing gas is supplied to the wafer W, while maintaining the supply of the Ar gas. The controller 9 performs control of opening the valve 52d, thereby supplying the nitrogen-containing gas from the reservoir tank 52e into the processing space 38 (Flow). Thus, the below-described adsorption layer is nitrided at step S104. Specifically, halogen groups (Cl) of the precursor adsorbed on the surface of the wafer W are substituted with amino groups (NH₂) of the nitrogen-containing gas (NH₃). After a set time has passed, the controller 9 performs control of closing the valve 52d. While the valve 52d is closed (see steps S103 to S105 in FIG. 3), the reservoir tank 52e is filled with the nitrogen-containing gas supplied from the first reaction gas source 52a (Fill). In FIG. 3, the flow rate of the nitrogen-containing gas supplied into the processing space 38 is indicated by a solid line, and the flow rate of the nitrogen-containing gas filling the reservoir tank 52e is indicated by a dashed line.

At step S103, the processing space 38 is purged, while maintaining the supply of the Ar gas. Thus, the excessive nitrogen-containing gas or the like in the processing space 38 is purged by the Ar gas. After a set purge time has passed, the operation of the controller 9 proceeds to step S104.

At step S104, the precursor gas is supplied to the wafer W, while maintaining the supply of the Ar gas. The controller 9 performs control of opening the valve 51d, thereby supplying the precursor gas from the precursor gas source 51a into the processing space 38 (Flow). Thus, the precursor is adsorbed on the surface of the wafer W, thereby forming an adsorption layer of the precursor on the surface of the wafer W. After the set time has passed, the controller 9 performs control of closing the valve 51d. While the valve 51d is closed (see steps S102 to S103 and S105 of FIG. 3), the reservoir tank 51e is filled with the precursor gas supplied from the precursor gas source 51a (Fill). In FIG. 3, the flow rate of the precursor gas supplied into the processing space 38 is indicated by a solid line, and the flow rate of the precursor gas filling the reservoir tank 51e is indicated by a dashed line.

At step S105, the processing space 38 is purged, while maintaining the supply of the Ar gas. Thus, the excessive precursor gas or the like in the processing space 38 is purged by the Ar gas. After a set purge time has passed, the operation of the controller 9 proceeds to step S106.

At step S106, the controller 9 determines whether or not the number of cycles executed has reached the set number X (X is one or more), where each cycle includes the operation of step S102 to step S105. In the case where the number of cycles executed has not reached the set number X (NO at S106), the operation of the controller 9 returns back to step S102, and the cycle of step S102 to step S105 is executed. When the number of cycles executed reaches the set number X (YES at S106), the counter for counting the number of cycles executed at times step S106 is reset, and the operation of the controller 9 proceeds to step S107. As the number X of cycles executed increases, frequency of a modification step (S109) decreases. As the number X of cycles executed decreases, frequency of the modification step (S109) increases.

Next, the controller 9 performs a second step (S107 to S110) of modifying the SiCN film formed on the wafer W.

At step S107, the processing space 38 is purged, while maintaining the supply of the Ar gas. During purging, the controller 9 controls the flow-rate regulators 55c and 56c to regulate the flow rate of the Ar gas, and controls the exhaust mechanism 42 to regulate the pressure in the processing space 38 (see Press. of FIG. 3). In this process, the conditions, which are the flow rate of the Ar gas and the pressure in the processing space 38, for the first step (see S102 to S106) of forming a film by the ALD cycles, are changed to the conditions, which are the flow rate of the Ar gas and the pressure in the processing space 38, for the second step (see S109) of modifying the film with hydrogen plasma. For example, the flow rate of the Ar gas in the second step is set to be larger than the flow rate of the Ar gas in the first step. In addition, for example, the pressure in the second step is set to be lower than the pressure in the first step. Since the flow rate of the Ar gas in the second step is set to be larger than the flow rate of the Ar gas in the first step, or the pressure in the second step is set to be smaller than the pressure in the first step, or both, a distribution of plasma is improved, thereby improving homogeneousness of the film thickness and the film quality in the planar direction. After adjusting the flow rate of the Ar gas and the pressure in the processing space 38, the operation of the controller 9 proceeds to step S108.

At step S108, the hydrogen-containing gas is supplied into the processing space 38, while maintaining the supply of the Ar gas. The controller 9 performs control of opening the valve 54d, thereby supplying the hydrogen-containing gas from the hydrogen gas source 54a to the processing space 38 (Flow).

At step S109, the insulation film (SiCN film) formed on the wafer W is modified with hydrogen plasma. The controller 9 controls the radio frequency power source 83 to apply a radio frequency (RF) power to the upper electrode, thereby generating plasma in the processing space 38. The power (RF power) applied from the RF power source 83 to the upper electrode, is for example, 10 W to 2,000 W, and the application time (RF time) is, for example, 0.1 sec to 10.0 sec. By exposing the wafer W to the plasma of the hydrogen-containing gas, the SiCN film formed on the wafer W is modified. After a set time has passed, the controller 9 performs control of stopping the application of RF to the upper electrode, and closing the valve 54d.

At the modification step, the insulation film (SiCN film) formed on the surface of the wafer W is exposed to hydrogen plasma so that dangling bonds, which are formed by cleavage of weak bonds, such as CH₃ groups or NH₂ groups in the insulation film, or removal of CHₓ or NHₓ as H₂ as a result of a reaction with hydrogen radicals, form new bonds, such as Si—O—Si, Si—C—Si, and Si—N—Si. Thus, the film is modified to have a firmer film quality. In other words, wet etching resistance of the insulation film (SiCN film) can be improved.

At step S110, the processing space 38 is purged, while maintaining the supply of the Ar gas. Thus, the excess hydrogen-containing gas or the like in the processing space 38 is purged by the Ar gas. During purging, the controller 9 controls the flow-rate regulators 55c and 56c to regulate the flow rate of the Ar gas, and controls the exhaust mechanism 42 to regulate the pressure in the processing space 38 (see Press. of FIG. 3). In this process, the conditions, which are the flow rate of the Ar gas and the pressure in the processing space 38, for the second step (see S109) for modifying the film with hydrogen plasma, are changed to the conditions, which are the flow rate of the Ar gas and the pressure in the processing space 38, for the first step (see S102 to S106) for forming the film by ALD cycles. After adjusting the flow rate of the Ar gas and the pressure in the processing space 38, the operation of the controller 9 proceeds to step S111.

At step S111, the controller 9 determines whether or not the number of cycles executed has reached the set number Y (Y is one or more), where each cycle includes the operation of step S102 to step S110. In the case where the number of cycles executed has not reached the set number Y (NO at S111), the controller 9 causes the process to return back to step S102, and the cycle of step S102 to step S110 is executed. When the number of cycles executed reaches the set number Y (YES at S111), the counter for counting the number of cycles executed at step S111 is reset, and the controller 9 ends the process illustrated in FIG. 2.

According to the method for forming the insulation film illustrated in FIGS. 2 and 3, the film formation progresses through substitution of halogen groups (Cl) of the silicon precursor (C₂H₄Cl₄Si₂) with amino groups (NH₂) of the nitrogen-containing gas (NH₃). Thus, C of alkyl groups of the silicon precursor is taken into the insulation film. Moreover, plasma of the nitrogen-containing gas is not required for nitriding. Therefore, desorption of C by plasma can be avoided. As a result, the insulation film (SiCN film) having a high C concentration can be formed. In addition, the film can be formed with desired coverage because the film is formed by ALD.

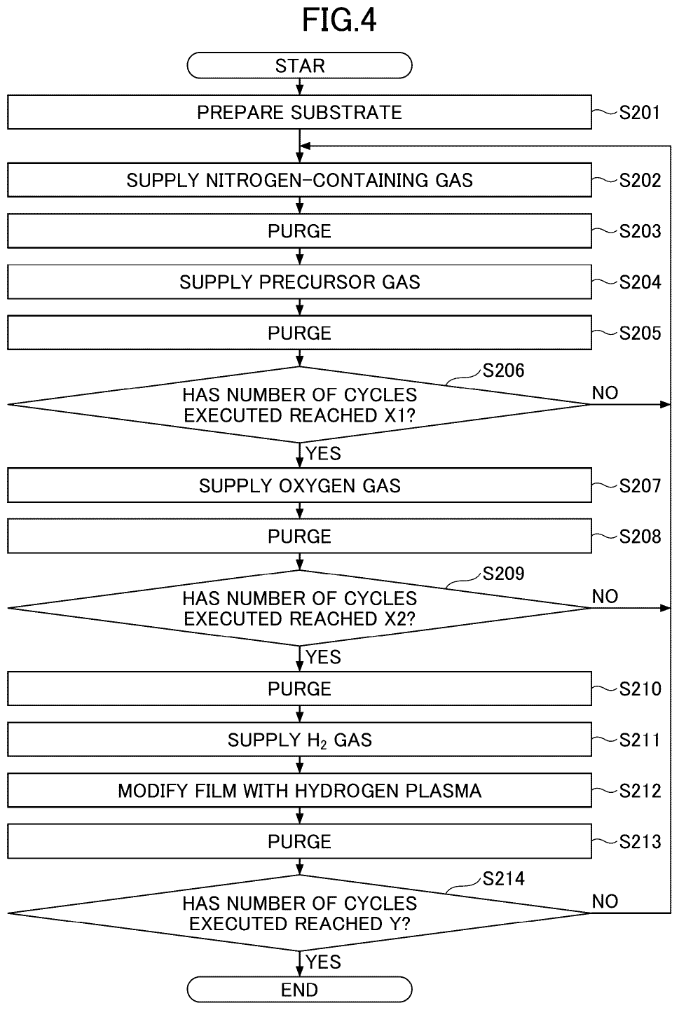

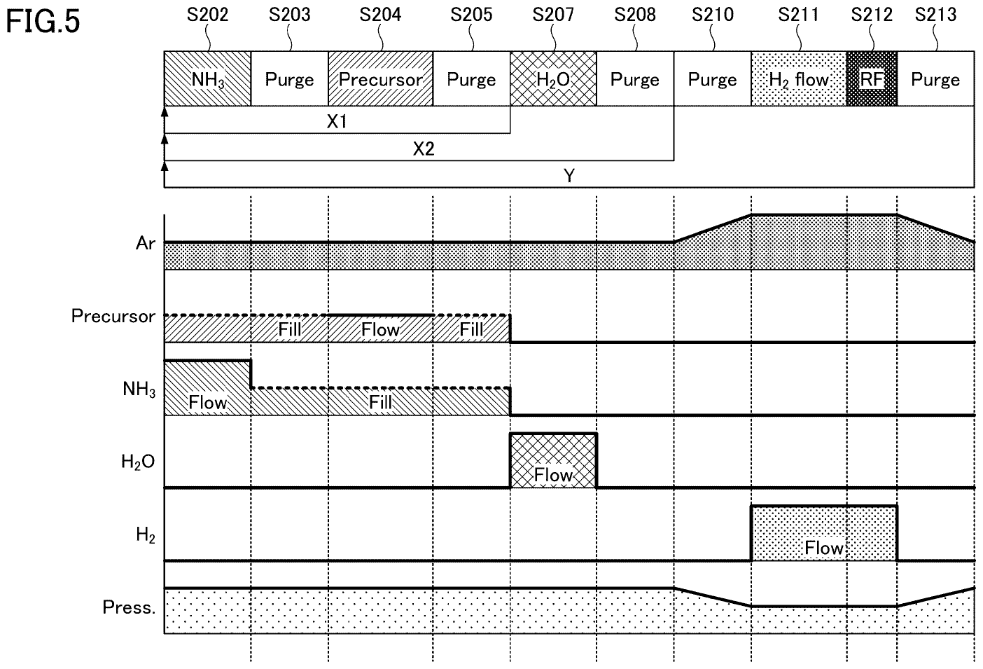

Next, another example of the operation of the substrate processing apparatus 100 will be described with reference to FIGS. 4 and 5. FIG. 4 is a flowchart illustrating another example of the substrate processing method according to the present embodiment. FIG. 5 is a time chart illustrating another example of the substrate processing method according to the present embodiment. In FIGS. 3 and 4, the example where the substrate processing apparatus 100 forms, as an insulation film, a SiOCN film on a wafer W is described.

In FIG. 5, “Ar” represents one example of a flow rate of an Ar gas; “Precursor” represents one example of a flow rate of a precursor gas; “NH₃” represents one example of a flow rate of a NH₃ gas serving as a nitrogen-containing gas; “H₂O” represents one example of a flow rate of H₂O gas serving as an oxygen-containing gas; “H₂” represents one example of a flow rate of a H₂ gas serving as a hydrogen-containing gas; and “Press.” represents one example of the pressure in a processing space 38.

At step S201, a wafer W is prepared. First, the wafer W is loaded into the processing chamber 1 of the substrate processing apparatus 100 illustrated in FIG. 1. Specifically, the gate valve 12 is opened in a state in which the stage 2 is lowered to a loading position. Subsequently, the wafer W is loaded into the processing chamber 1 through a loading port 11 by a transfer arm (not illustrated), and is placed on the stage 2 heated at a set temperature (e.g., 200° C. to 500° C.) by a heater 21. Subsequently, the stage 2 is lifted to the processing position, and the inner atmosphere of the processing chamber 1 is depressurized by the exhaust mechanism 42 to a set degree of vacuum. After depressurizing, the controller 9 performs control of opening the valves 55d and 56d, thereby supplying an Ar gas from the carrier gas/purge gas sources 55a and 56a. Thus, the inner atmosphere of the processing chamber 1 is stabilized at a set pressure.

Next, the controller 9 performs a first step (S202 to S206) of forming a SiOCN film on the wafer W.

At step S202, a nitrogen-containing gas is supplied to the wafer W, while maintaining the supply of the Ar gas. The controller 9 performs control of opening the valve 52d, thereby supplying the nitrogen-containing gas from the reservoir tank 52e into the processing space 38 (Flow). Thus, the below-described adsorption layer is nitrided at step S204. Specifically, halogen groups (Cl) of the precursor adsorbed on the surface of the wafer W are substituted with amino groups (NH₂) of the nitrogen-containing gas (NH₃). After a set time has passed, the controller 9 performs control of closing the valve 52d. While the valve 52d is closed (see steps S203 to S205 in FIG. 5), the reservoir tank 52e is filled with the nitrogen-containing gas supplied from the first reaction gas source 52a (Fill). In FIG. 5, the flow rate of the nitrogen-containing gas supplied into the processing space 38 is indicated by a solid line, and the flow rate of the nitrogen-containing gas filling the reservoir tank 52e is indicated by a dashed line.

At step S203, the processing space 38 is purged, while maintaining the supply of the Ar gas. Thus, the excessive nitrogen-containing gas or the like in the processing space 38 is purged by the Ar gas. After a set purge time has passed, the operation of the controller 9 proceeds to step S204.

At step S204, the precursor gas is supplied to the wafer W, while maintaining the supply of the Ar gas. The controller 9 performs control of opening the valve 51d, thereby supplying the precursor gas from the precursor gas source 51a into the processing space 38 (Flow). Thus, the precursor is adsorbed on the surface of the wafer W, thereby forming an adsorption layer of the precursor on the surface of the wafer W. After the set time has passed, the controller 9 performs control of closing the valve 51d. While the valve 51d is closed (see steps S202 to S203 and S205 of FIG. 5), the reservoir tank 51e is filled with the precursor gas supplied from the precursor gas source 51a (Fill). In FIG. 5, the flow rate of the precursor gas supplied into the processing space 38 is indicated by a solid line, and the flow rate of the precursor gas filling the reservoir tank 51e is indicated by a dashed line.

At step S205, the processing space 38 is purged, while maintaining the supply of the Ar gas. Thus, the excessive precursor gas or the like in the processing space 38 is purged by the Ar gas. After a set purge time has passed, the operation of the controller 9 proceeds to step S206.

At step S206, the controller 9 determines whether or not the number of cycles executed has reached the set number X1 (X1 is one or more), where each cycle includes the operation of step S202 to step S205. In the case where the number of cycles executed has not reached the set number X1 (NO at S206), the operation of the controller 9 returns back to step S202, and the cycle of step S202 to step S205 is executed. When the number of cycles executed reaches the set number X1 (YES at S206), the counter for counting the number of cycles executed at times step S206 is reset, and the operation of the controller 9 proceeds to step S207. As the number X1 of cycles executed increases, frequency of an oxidation step (S207) decreases. As the number X1 of cycles executed decreases, frequency of the oxidation step (S207) increases.

At step S207, an oxygen-containing gas was supplied to the wafer W, while maintaining the supply of the Ar gas. The controller 9 performs control of opening the valve 53d, thereby supplying the oxygen-containing gas from the second reaction gas source 53a into the processing space 38. Thus, the adsorption layer on the surface of the wafer W is oxidized. Specifically, halogen groups (Cl) of the precursor adsorbed on the surface of the wafer W are substituted with hydroxyl groups (OH) of the oxygen-containing gas (H₂O). After a set time has passed, the controller 9 performs control of closing the valve 53d.

At step S208, the processing space 38 is purged, while maintaining the supply of the Ar gas. Thus, the excess oxygen-containing gas or the like in the processing space 38 is purged by the Ar gas. After a set purge time has passed, the operation of the controller 9 proceeds to step S209.

At step S209, the controller 9 determines whether or not the number of cycles executed has reached the set number X2 (X2 is 1 or more), where each cycle includes the operation of step S202 to step S208. In the case where the number of cycles executed has not reached the set number X2 (NO at S209), the operation of the controller 9 returns back to step S202, and the cycle of step S202 to step S208 is executed. When the number of cycles executed reaches the set number X2 (YES at S209), the counter for counting the number of cycles executed at times step S209 is reset, and the operation of the controller 9 proceeds to step S210. As the product of the number X1 of cycles executed and the number X2 of cycles executed increases, frequency of a modification step (S212) decreases. As the product of the number X1 of cycles executed and the number X2 of cycles executed decreases, frequency of the modification step (S212) increases.

Next, the controller 9 performs a second step (S210 to S213) of modifying the SiOCN film formed on the wafer W.

At step S210, the processing space 38 is purged, while maintaining the supply of the Ar gas. During purging, the controller 9 controls the flow-rate regulators 55c and 56c to regulate the flow rate of the Ar gas, and controls the exhaust mechanism 42 to regulate the internal pressure of the processing space 38 (see Press. of FIG. 5). In this process, the conditions, which are the flow rate of the Ar gas and the pressure in the processing space 38, for the first step (see S202 to S206) of forming a film by the ALD cycles, are changed to the conditions, which are the flow rate of the Ar gas and the pressure in the processing space 38, for the second step (see S212) of modifying the film with hydrogen plasma. For example, the flow rate of the Ar gas in the second step is set to be larger than the flow rate of the Ar gas in the first step. In addition, for example, the pressure in the second step is set to be lower than the pressure in the first step. Since the flow rate of the Ar gas in the second step is set to be larger than the flow rate of the Ar gas in the first step, or the pressure in the second step is set to be smaller than the pressure in the first step, or both, a distribution of plasma is improved, thereby improving homogeneousness of the film thickness and the film quality in the planar direction. After adjusting the flow rate of the Ar gas and the pressure in the processing space 38, the operation of the controller 9 proceeds to step S211.

At step S211, the hydrogen-containing gas is supplied into the processing space 38, while maintaining the supply of the Ar gas. The controller 9 performs control of opening the valve 54d, thereby supplying the hydrogen-containing gas from the hydrogen gas source 54a to the processing space 38 (Flow).

At step S212, the insulation film (SiOCN film) formed on the wafer W is modified with hydrogen plasma. The controller 9 controls the radio frequency power source 83 to apply a radio frequency (RF) power to the upper electrode, thereby generating plasma in the processing space 38. The power (RF power) applied from the RF power source 83 to the upper electrode, is for example, 10 W to 2,000 W, and the application time (RF time) is, for example, 0.1 sec to 10.0 sec. By exposing the wafer W to the plasma of the hydrogen-containing gas, the SiOCN film formed on the wafer W is modified. After a set time has passed, the controller 9 performs control of stopping the application of RF to the upper electrode, and closing the valve 54d.

At the modification step, the insulation film (SiOCN film) formed on the surface of the wafer W is exposed to hydrogen plasma so that dangling bonds, which are formed by cleavage of weak bonds, such as CH₃ groups or NH₂ groups in the insulation film, or removal of CHₓ or NHₓ as H₂ as a result of a reaction with hydrogen radicals, form new bonds, such as Si—O—Si, Si—C—Si, and Si—N—Si. Thus, the film is modified to have a firmer film quality. In other words, wet etching resistance of the insulation film (SiOCN film) can be improved.

At step S213, the processing space 38 is purged, while maintaining the supply of the Ar gas. Thus, the excess hydrogen-containing gas or the like in the processing space 38 is purged by the Ar gas. During purging, the controller 9 controls the flow-rate regulators 55c and 56c to regulate the flow rate of the Ar gas, and controls the exhaust mechanism 42 to regulate the pressure in the processing space 38 (see Press. of FIG. 5). In this process, the conditions, which are the flow rate of the Ar gas and the pressure in the processing space 38, for the second step (see S212) for modifying the film with hydrogen plasma, are changed to the conditions, which are the flow rate of the Ar gas and the pressure in the processing space 38, for the first step (see S202 to S206) for forming the film by ALD cycles. After adjusting the flow rate of the Ar gas and the pressure in the processing space 38, the operation of the controller 9 proceeds to step S214.

At step S214, the controller 9 determines whether or not the number of cycles executed has reached the set number Y (Y is one or more), where each cycle includes the operation of step S202 to step S213. In the case where the number of cycles executed has not reached the set number Y (NO at S214), the operation of the controller 9 returns back to step S202, and the cycle of step S202 to step S213 is executed. When the number of cycles executed reaches the set number Y (YES at S214), the counter for counting the number of cycles executed at step S214 is reset, and the controller 9 ends the process illustrated in FIG. 4.

According to the method for forming the insulation film illustrated in FIGS. 4 and 5, the film formation progresses through substitution of halogen groups (Cl) of the silicon precursor (C₂H₄Cl₄Si₂) with amino groups (NH₂) of the nitrogen-containing gas (NH₃). Thus, C of alkyl groups of the silicon precursor is taken into the insulation film. Moreover, plasma of the nitrogen-containing gas is not required for nitriding. Therefore, the desorption of C by plasma can be avoided. As a result, the insulation film (SiOCN film) having a high C concentration can be formed. In addition, the film can be formed with desired coverage because the film is formed by ALD.

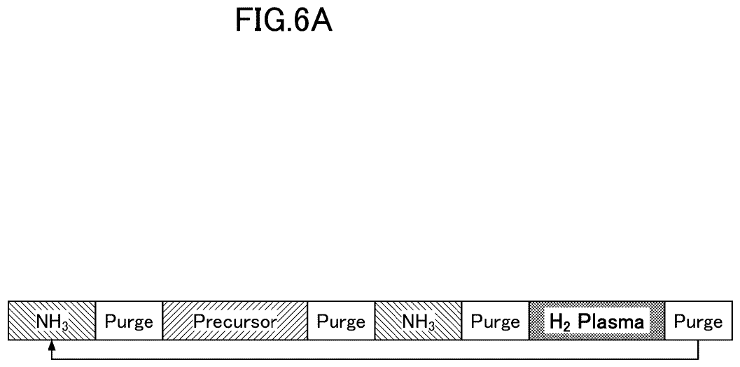

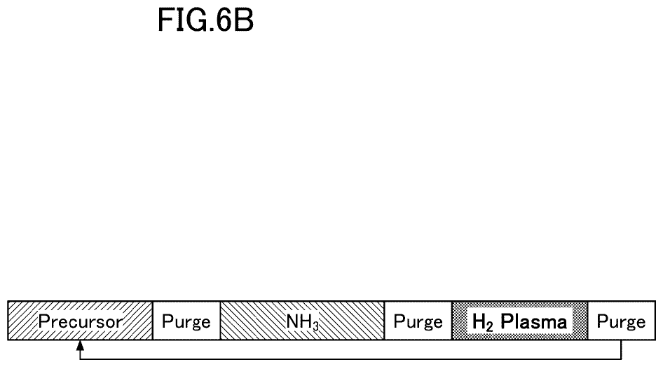

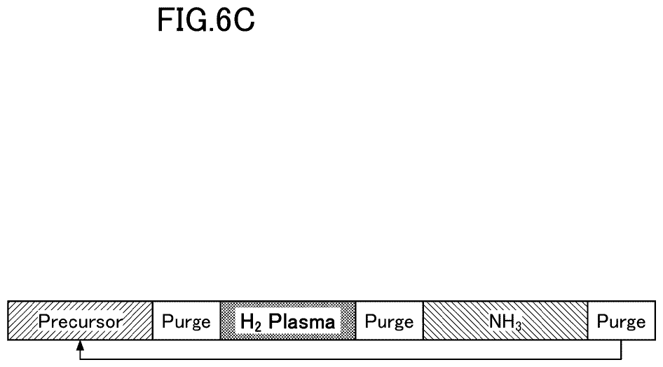

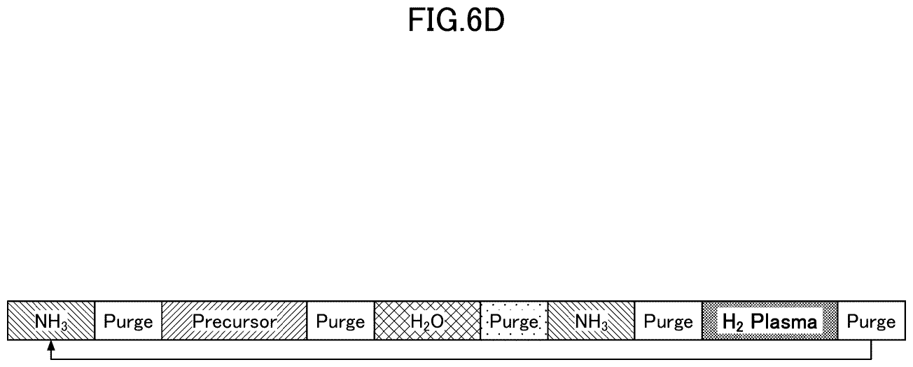

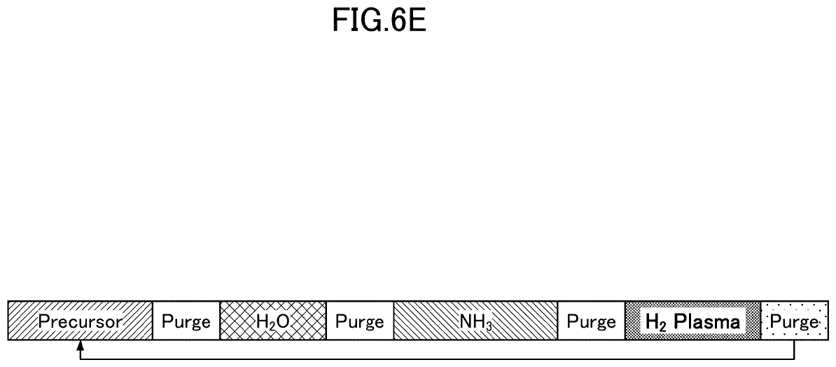

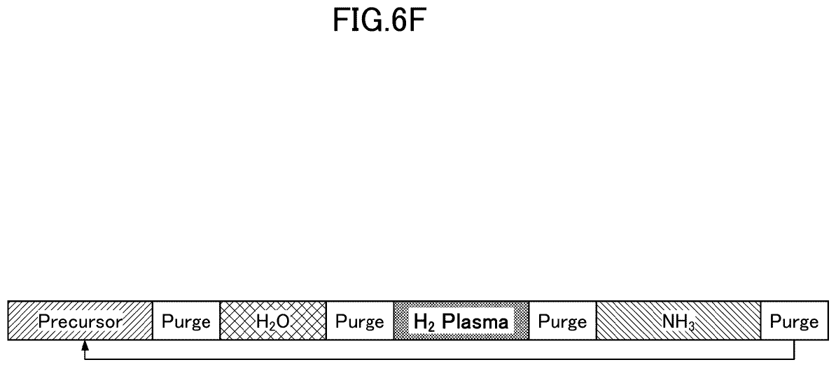

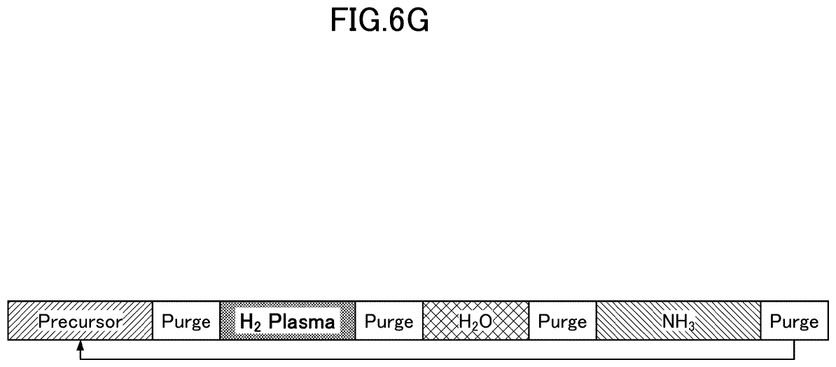

Next, a relationship between the timing for performing the second step (see S109 and S212) of modifying the film with hydrogen plasma and properties of the formed insulation film will be described with reference to FIGS. 6A to 11.

FIGS. 6A to 6G are examples of the time chart of the ALD cycle for forming the insulation film. FIGS. 6A to 6C depict the process of forming a SiCN film by an ALD cycle. FIGS. 6D to 6G depict the process of forming a SiOCN film by an ALD cycle.

FIG. 6A (may be referred to as Step (a) hereinafter) depicts a cycle including a step of supplying a nitrogen-containing gas (NH₃: corresponding to step S102), a step of purging the processing space 38 (Purge: corresponding to step S103), a step of supplying a precursor gas (Precursor: corresponding to step S104), a step of purging the processing space 38 (Purge: corresponding to step S105), a step of supplying a nitrogen-containing gas (NH₃: corresponding to step S102), a step of purging the processing space 38, and adjusting the flow rate of Ar and the pressure in the processing space 38 (Purge: corresponding to step S107), a step of modifying the film with hydrogen plasma (H₂ Plasma: corresponding to steps S108 and S109), and a step of purging the processing space 38, and adjusting the flow rate of Ar and the pressure in the processing space 38 (Purge: corresponding to step S110) in this order. By executing the cycle the set number of times, a SiCN film is formed. Specifically, Step (a) includes the step of supplying the nitrogen-containing gas before and after the step of modifying the film with hydrogen plasma.

FIG. 6B (may be referred to as Step (b) hereinafter) depicts a cycle including a step of supplying a precursor gas (Precursor: corresponding to step S104), a step of purging the processing space 38 (Purge: corresponding to step S105), a step of supplying a nitrogen-containing gas (NH₃: corresponding to step S102), a step of purging the processing space 38, and adjusting the flow rate of Ar and the pressure in the processing space 38 (Purge: corresponding to step S107), a step of modifying the film with hydrogen plasma (H₂ Plasma: corresponding to steps S108 and S109), and a step of purging the processing space 38, and adjusting the flow rate of Ar and the pressure in the processing space 38 (Purge: corresponding to step S110) in this order. By executing the cycle the set number of times, a SiCN film is formed. Specifically, Step (b) includes the step of supplying the nitrogen-containing gas before the step of modifying the film with hydrogen plasma.

FIG. 6C (may be referred to as Step (c) hereinafter) depicts a cycle including a step of supplying a precursor gas (Precursor: corresponding to step S104), a step of purging the processing space 38, and adjusting the flow rate of Ar and the pressure in the processing space 38 (Purge: corresponding to step S107), a step of modifying the film with hydrogen plasma (H₂ Plasma: corresponding to steps S108 and S109), a step of purging the processing space 38, and adjusting the flow rate of Ar and the pressure in the processing space 38 (Purge: corresponding to step S110), a step of supplying a nitrogen-containing gas (NH₃: corresponding to step S102), and a step of purging the processing space 38 (Purge: corresponding to step S103) in this order. By executing the cycle the set number of times, a SiCN film is formed. Specifically, Step (c) includes the step of supplying the nitrogen-containing gas after the step of modifying the film with hydrogen plasma. Moreover, Step (c) corresponds to the SiCN film formation process illustrated in FIGS. 2 and 3.

FIG. 6D (may be referred to as Step (d) hereinafter) depicts a cycle including a step of supplying a nitrogen-containing gas (NH₃: corresponding to step S202), a step of purging the processing space 38 (Purge: step S203), a step of supplying a precursor gas (Precursor: corresponding to step S204), a step of purging the processing space 38 (Purge: corresponding to step S205), a step of supplying an oxygen-containing gas (H₂O: corresponding to step S207), a step of purging the processing space 38 (Purge: corresponding to step S208), a step of supplying a nitrogen-containing gas (NH₃: corresponding to step S202), a step of purging the processing space 38, and adjusting the flow rate of Ar and the pressure in the processing space 38 (Purge: corresponding to step S210), a step of modifying the film with hydrogen plasma (H₂ Plasma: corresponding to steps S211 and S212), and a step of purging the processing space 38, and adjusting the flow rate of Ar and the pressure in the processing space 38 (Purge: corresponding to step S213) in this order. By executing the cycle the set number of times, a SiOCN film is formed. Specifically, Step (d) includes the step of supplying the nitrogen-containing gas before and after the step of modifying the film with hydrogen plasma.

FIG. 6E (may be referred to as Step (e) hereinafter) depicts a cycle including a step of supplying a precursor gas (Precursor: corresponding to step S204), a step of purging the processing space 38 (Purge: corresponding to step S205), a step of supplying an oxygen-containing gas (H₂O: corresponding to step S207), a step of purging the processing space 38 (Purge: corresponding to step S208), a step of supplying a nitrogen-containing gas (NH₃: corresponding to step S202), a step of purging the processing space 38, and adjusting the flow rate of Ar and the pressure in the processing space 38 (Purge: corresponding to step S210), a step of modifying the film with hydrogen plasma (H₂ Plasma: corresponding to steps S211 and S212), and a step of purging the processing space 38, and adjusting the flow rate of Ar and the pressure in the processing space 38 (Purge: corresponding to step S213) in this order. By executing the cycle the set number of times, a SiOCN film is formed. Specifically, Step (e) includes the step of supplying the nitrogen-containing gas before the step of modifying the film with hydrogen plasma.

FIG. 6F (may be referred to as Step (f) hereinafter) depicts a cycle including a step of supplying a precursor gas (Precursor: corresponding to step S204), a step of purging the processing space 38 (Purge: corresponding to step S205), a step of supplying an oxygen-containing gas (H₂O: corresponding to step S207), a step of purging the processing space 38, and adjusting the flow rate of Ar and the pressure in the processing space 38 (Purge: corresponding to step S210), a step of modifying the film with hydrogen plasma (H₂ Plasma: corresponding to steps S211 and S212), a step of purging the processing space 38, and adjusting the flow rate of Ar and the pressure in the processing space 38 (Purge: corresponding to step S213), a step of supplying a nitrogen-containing gas (NH₃: corresponding to step S202), and a step of purging the processing space 38 (Purge: corresponding to step S203) in this order. By executing the cycle the set number of times, a SiOCN film is formed. Specifically, Step (f) includes the step of supplying the oxygen-containing gas before the step of modifying the film with hydrogen plasma, and includes the step of supplying the nitrogen-containing gas after the step of modifying the film with hydrogen plasma. Moreover, Step (f) corresponds to the SiOCN film formation process illustrated in FIGS. 4 and 5.

FIG. 6G (may be referred to as Step (g) hereinafter) depicts a cycle including a step of supplying a precursor gas (Precursor: corresponding to step S204), a step of purging the processing space 38, and adjusting the flow rate of Ar and the pressure in the processing space 38 (Purge: corresponding to step S210), a step of modifying the film with hydrogen plasma (H₂ Plasma: corresponding to steps S211 and S212), a step of purging the processing space 38, and adjusting the flow rate of Ar and the pressure in the processing space 38 (Purge: corresponding to S213), a step of supplying an oxygen-containing gas (H₂O: corresponding to S207), a step of purging the processing space 38 (Purge: corresponding to step S208), a step of supplying a nitrogen-containing gas (NH₃: corresponding to step S202), and a step of purging the processing space 38 (Purge: corresponding to step S203) in this order. By executing the cycle the set number of times, a SiOCN film is formed. Specifically, Step (g) includes the step of supplying the oxygen-containing gas and the step of supplying the nitrogen-containing gas after the step of modifying the film with hydrogen plasma.

The process conditions of each cycle are as follows.
Precursor gas: 10 sccm to 100 sccm
Nitrogen-containing gas: 1,000 sccm to 10,000 sccm
Oxygen-containing gas: 100 sccm to 1,000 sccm
Hydrogen gas: 1,000 sccm to 5,000 sccm
Carrier/purge gas (Ar): 500 sccm to 6,000 sccm
Temperature: 200° C. to 500° C.
Pressure (first step): 200 Pa to 3,000 Pa
Pressure (second step): 200 Pa to 3,000 Pa
RF power: 10 W to 2,000 W

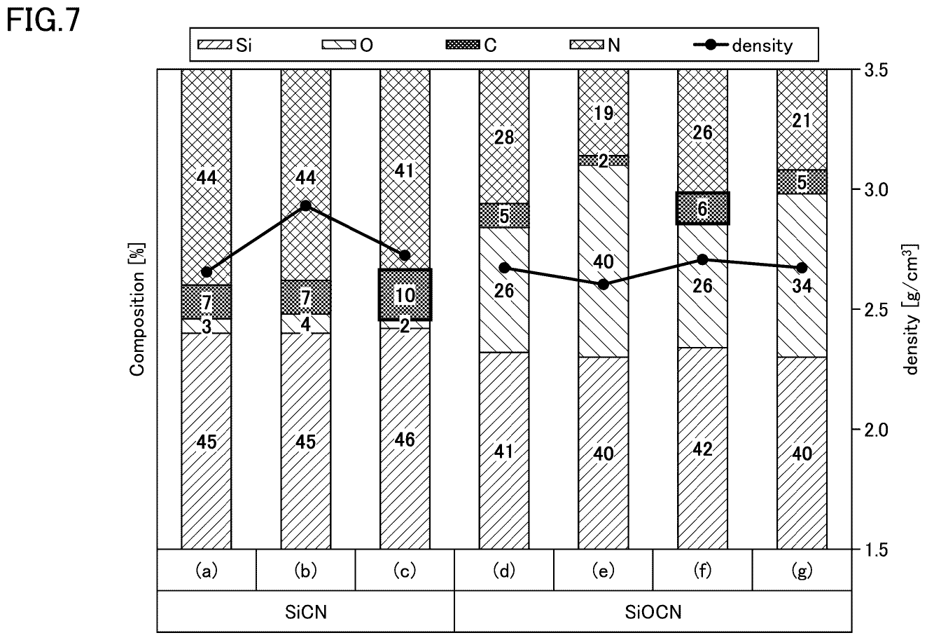

The compositions and densities of the insulation films formed by the ALD cycles depicted in Steps (a) to (g) of FIGS. 6A to 6G are presented in FIG. 7. FIG. 7 is an example of a graph representing the compositions and densities of the formed insulation films. In FIG. 7, (a) to (g) on the horizontal axis correspond to Steps (a) to (g) of FIGS. 6A to 6G, respectively. In addition, the compositions of the insulation films are represented by a bar graph. Further, the densities of the insulation films are represented by a line graph.

It was confirmed that, among Steps (a) to (c) for forming a SiCN film, the concentration of carbon (C) in the composition can be increased by performing film formation with the cycle of Step (c), compared with film formation performed with other cycles.

It was confirmed that, among steps (d) to (g) for forming a SiOCN film, the concentration of carbon (C) in the composition can be increased by performing film formation with the cycle of Step (f), compared with film formation performed with other cycles.

It was confirmed that, among steps (a) to (g) for forming a SiCN film, the density of the insulation film formed with the cycle of Step (c) was comparable with the densities of the films formed with other cycles.

It was confirmed that, among steps (d) to (g) for forming a SiOCN film, the density of the insulation film formed with the cycle of Step (f) was comparable with the densities of the films formed with other cycles.

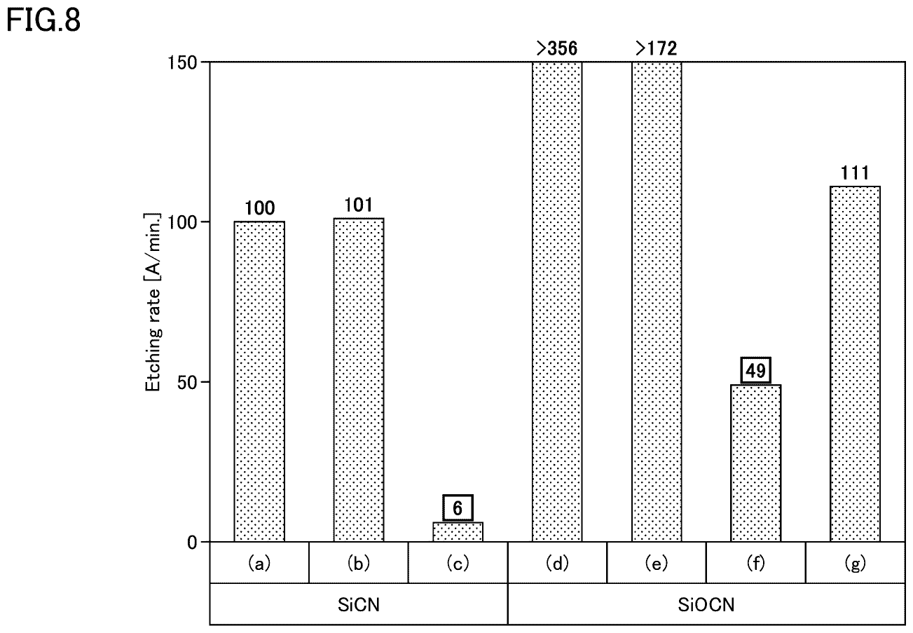

FIG. 8 presents wet etching resistance of the formed insulation films formed with the cycles of Steps (a) to (g) of FIGS. 6A to 6G. FIG. 8 is one example of a graph presenting wet etching resistance of the formed insulation films. In FIG. 8, (a) to (g) on the horizontal axis correspond to Steps (a) to (g) of FIGS. 6A to 6G, respectively. In addition, the etching rates of the insulation films with respect to 50% DHF are presented by a bar graph.

It was confirmed that, among Steps (a) to (c) for forming a SiCN film, the wet etching resistance was improved by performing film formation with the cycle of Step (c), compared with film formation performed with other cycles.

It was confirmed that, among Steps (d) to (g) for forming a SiOCN film, the wet etching resistance was improved by performing film formation with the cycle of Step (f), compared with film formation performed with other cycles.

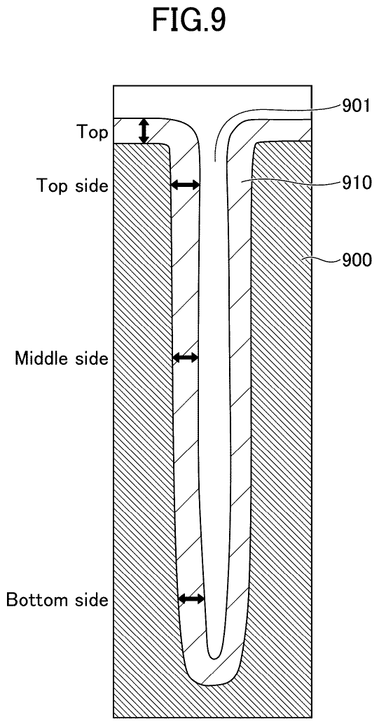

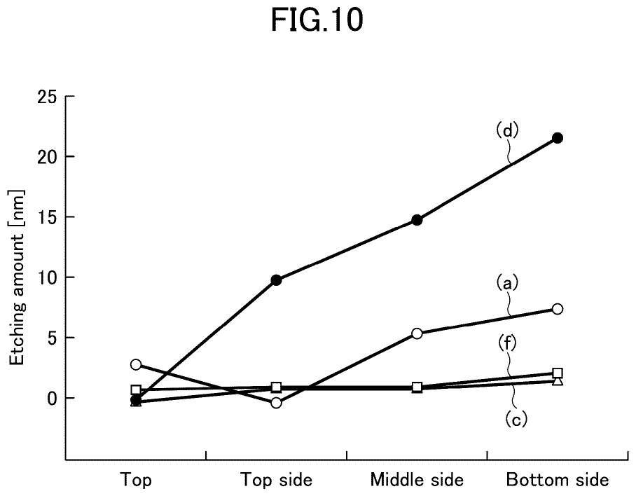

The wet etching resistance of the insulation film formed on a trench will be described with reference to FIGS. 9 and 10. FIG. 9 is an example of a schematic view illustrating the insulation film formed on the trench. A film 900 is formed on a wafer W. A pattern of a recess 901, such as a trench or the like, is formed in the film 900. An insulation film 910 is formed on a surface of the wafer W by the substrate processing apparatus 100. In FIG. 9, a portion of the insulation film formed on the upper surface of the recess 901 of the wafer is referred to as “Top.” A portion of the insulation film formed on the side surface of the recess 901 of the wafer W and at the center portion in the depth direction of the recess 901 is referred to as “Middle Side.” A portion of the insulation film formed on the side surface of the recess 901 of the wafer W and at the position closer to the opening side of the recess 901 with respect to the center portion in the depth direction of the recess 901 is referred to as “Top Side.” A portion of the insulation film formed on the side surface of the recess 901 of the wafer W and at the position closer to the bottom of the recess 901 with respect to the center portion in the depth direction of the recess 901 is referred to as “Bottom Side.”

FIG. 10 is an example of a graph presenting the etching amounts of the insulation films, each formed on the side surface of the trench. With cycles depicted in Steps (a), (c), (d), and (f), insulation films were formed, respectively. Each insulation film was formed on a wafer W having a recess. Then, wet etching was performed with 5% DHF for 1 minute. The horizontal axis of FIG. 10 corresponds to “Top,” “Top Side,” “Middle Side,” and “Bottom Side” presented in FIG. 9. The vertical axis of FIG. 10 represents the etching amount when wet etching is performed with 5% DHF for 1 minute.

Step (a) and Step (c) for forming a SiCN film will be described. In the insulation film formed with the cycle of Step (a), the etching amount was increased at “Middle Side” and “Bottom Side.” Thus, the difference between the etching rate of the insulation film on the trench top surface (“Top”) and the etching rate of the insulation film on the trench side surface (“Middle Side” and “Bottom Side”) was large.

On the other hand, it was confirmed that the etching resistance of the insulation film formed on the side wall of the trench with the cycle of Step (c) was improved compared with the insulation film formed with the cycle of Step (a). Moreover, it was confirmed that the difference between the etching rate of the insulation film on the trench top surface (“Top”) and the etching rate of the insulation film on the trench side surface (“Middle Side” and “Bottom Side”) was reduced. In other words, the etching resistance of the entire insulation film formed on the trench with the cycle of Step (c) could be improved.

Step (d) and Step (f) for forming a SiOCN film will be described. In the insulation film formed with the cycle of Step (d), the etching amounts were increased at “Top Side,” “Middle Side,” and “Bottom Side.” Thus, the difference between the etching rate of the insulation film on the trench top surface (“Top”) and the etching rate of the insulation film on the trench side surface (“Top Side,” “Middle Side,” and “Bottom Side”) was large.

On the other hand, it was confirmed that the etching resistance of the insulation film formed on the side wall of the trench with the cycle of Step (f) was improved compared with the insulation film formed with the cycle of Step (d). Moreover, it was confirmed that the difference between the etching rate of the insulation film on the trench top surface (“Top”) and the etching rate of the insulation film on the trench side surface (“Top Side,” “Middle Side,” and “Bottom Side”) was reduced. In other words, the etching resistance of the entire insulation film formed on the trench with the cycle of Step (f) could be improved.

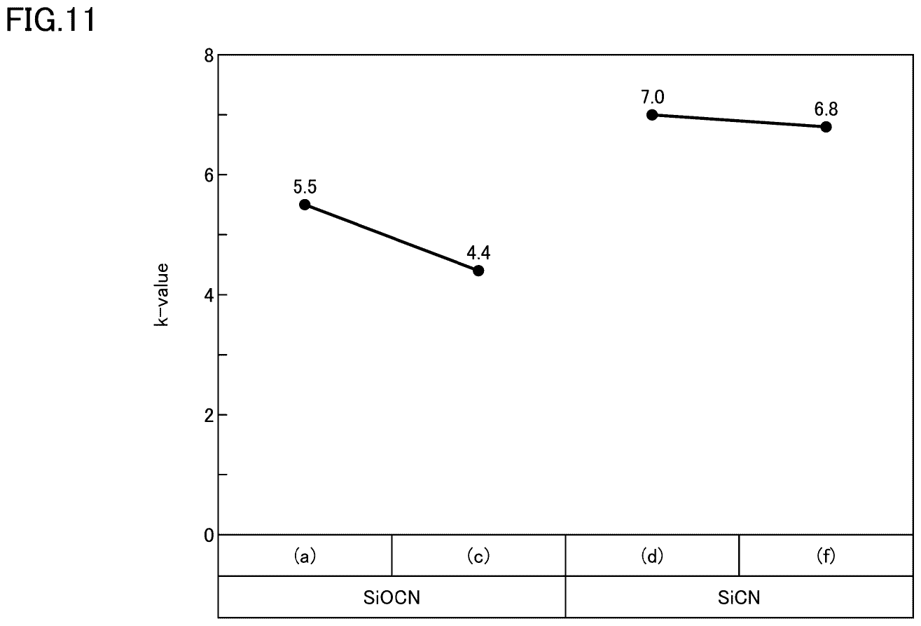

FIG. 11 is an example of a graph presenting dielectric constants of the insulation films. The insulation films were formed with cycles of Steps (a), (c), (d), and (f), respectively, and dielectric constants (k-values) of the insulation films were detected.

It was confirmed that, between Steps (a) and (c) for forming a SiCN film, a dielectric constant was also reduced by performing film formation with the cycle of Step (c) compared with the film formation performed with the cycle of Step (a).

It was confirmed that, between Steps (d) and (f) for forming a SiOCN film, a dielectric constant was also reduced by performing film formation with the cycle of Step (f), compared with the film formation performed with the cycle of Step (d).

As described above, wet etching resistance can be improved, and a dielectric constant is also reduced by setting the timing for performing the second step (see S109 and S212) of modifying the film with hydrogen plasma to the timing depicted in Step (c) of FIG. 6C and Step (f) of FIG. 6F. In particular, as presented in FIG. 10, the difference between the etching rate of the insulation film on the trench top surface and the etching rate of the insulation film on the trench side surface can be reduced.

Specifically, as depicted in Step (c) of FIG. 6C and Step (f) of FIG. 6F, the sequence of the steps is arranged such that nitriding (NH₃: corresponding to step S102 and step S202) is performed after the processing with hydrogen plasma (H₂ Plasma: corresponding to steps S108 and S109, and steps S211 and S212). Thus, desorption of carbon (C) in the insulation film is minimized as depicted in FIG. 7. In addition, many structural moieties, such as Si—C and Si—N, are formed in the insulation film. Since many structural moieties are formed, DHF resistance of the insulation film is improved as presented in FIG. 8.

As presented in FIG. 10, when film formation was performed with the sequence of a referential example (see Step (a) of FIG. 6A and Step (d) of FIG. 6D), DHF resistance of the insulation film formed on the trench side surface was insufficient. Conversely, when film formation was performed with the sequence in which nitriding was performed after processing with hydrogen plasma (see Step (c) of FIG. 6C and Step (f) of FIG. 6F), DHF resistance of the insulation film formed on the trench side surface was improved. In addition, the difference in etching rate between the upper portion (Top Side) and the lower portion (Bottom Side) of the insulation film formed on the trench side surface was reduced.

As presented in FIG. 11, when film formation was performed with the sequence in which nitriding was performed after the processing with hydrogen plasma (see Step (c) of FIG. 6C and Step (f) of FIG. 6F), desorption of carbon (C) in the insulation film was minimized so that the dielectric constant of the insulation film was low compared with the dielectric constant of the insulation film formed with the sequence of the referential example (see Step (a) of FIG. 6A and Step (d) of FIG. 6D).

As described above, by forming an insulation film with a sequence in which nitriding is performed after processing with hydrogen plasma, the insulation film having a low dielectric constant and high DHF resistance can be formed, compared with the insulation film formed with the sequence of the referential example.

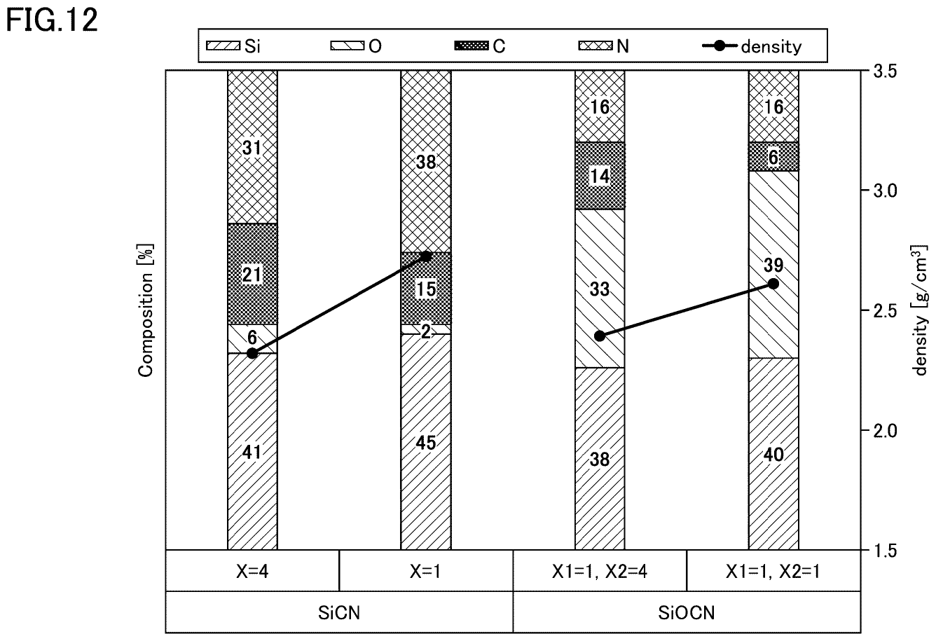

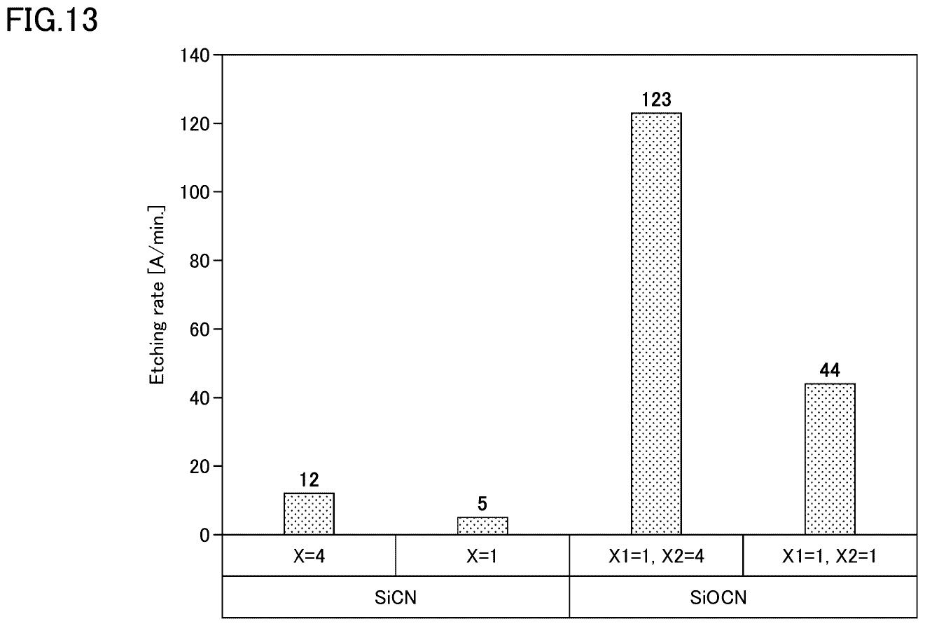

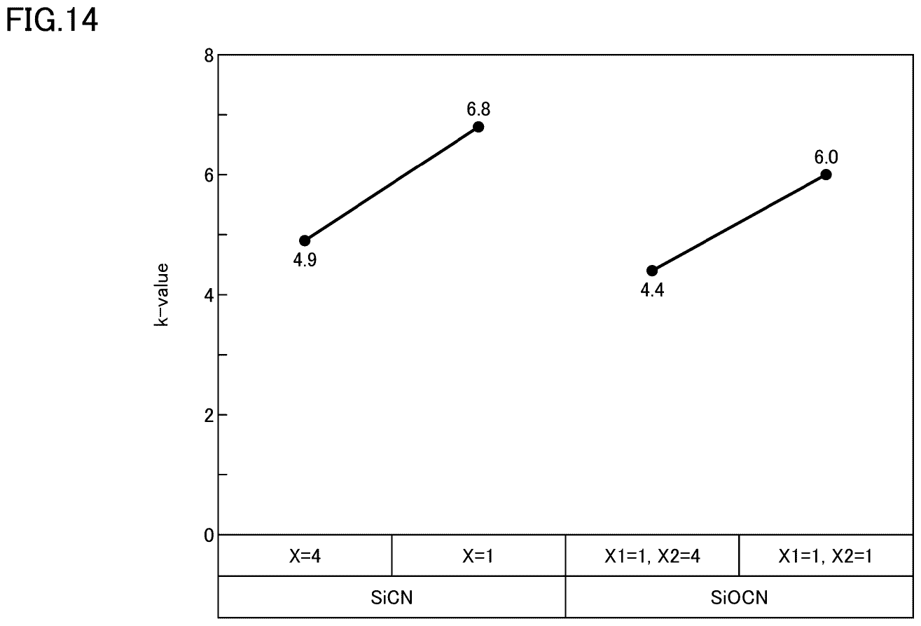

Next, the relationship between frequency of the second step (see S109 and S212) of modifying the film with hydrogen plasma and properties of the formed insulation film will be described with reference to FIGS. 12 to 14. FIG. 12 is an example of a graph presenting compositions and densities of the formed insulation films. FIG. 13 is an example of a graph presenting wet etching resistance of the formed insulation film. FIG. 14 is an example of a graph presenting dielectric constants of the insulation films.

In FIGS. 12 to 14, “X=4” represents that the film formation illustrated in FIGS. 2 and 3 was performed with the number X of cycles executed being 4 in step S106. Specifically, a SiCN film was formed by performing the step of modifying the film with hydrogen plasma (Step S108 and S109) after every 4 cycles, where each cycle included a step of supplying a nitrogen-containing gas (step S102) and a cycle of supplying a precursor gas (step S104) in this order.

In FIGS. 12 to 14, “X=1” represents that the film formation illustrated in FIGS. 2 and 3 was performed with the number X of cycles executed being 1 in step S106. Specifically, a SiCN film was formed by performing the step of modifying the film with hydrogen plasma (Step S108 and S109) after each cycle, where each cycle included a step of supplying a nitrogen-containing gas (step S102) and a cycle of supplying a precursor gas (step S104) in this order.

In FIGS. 12 to 14, “X1=1, X2=4” represents that the film formation illustrated in FIGS. 4 and 5 was performed with the number X1 of cycles executed being 1 in step S206 and the number X2 of cycles executed being 4 in step S209. Specifically, a SiOCN film was formed by performing the step of modifying the film with hydrogen plasma (step S211 and S212) after every 4 cycles, where each cycle included a step of supplying a nitrogen-containing gas (step S202), a step of supplying a precursor gas (step S204), and a step of supplying an oxygen-containing gas (step S207) in this order.

In FIGS. 12 to 14, “X1=1, X2=1” represents that the film formation illustrated in FIGS. 4 and 5 was performed with the number X1 of cycles executed being 1 in step S206 and the number X2 of cycles executed being 1 in step S209. Specifically, a SiOCN film was formed by performing the step of modifying the film with hydrogen plasma (step S211 and S212) after each cycle, where each cycle included a step of supplying a nitrogen-containing gas (step S202), a step of supplying a precursor gas (step S204), and a step of supplying an oxygen-containing gas (step S207) in this order.

The process conditions of each cycle are as follows.
Precursor gas: 10 sccm to 100 sccm
Nitrogen-containing gas: 1,000 sccm to 10,000 sccm
Oxygen-containing gas: 100 sccm to 1,000 sccm
Hydrogen gas: 1,000 sccm to 5,000 sccm
Carrier/purge gas (Ar): 500 sccm to 6,000 sccm
Temperature: 200° C. to 500° C.
Pressure (first step): 200 Pa to 3,000 Pa
Pressure (second step): 200 Pa to 3,000 Pa
RF power: 10 W to 2,000 W

As presented in FIG. 12 by comparing “X=4” and “X=1,” the composition ratio of the insulation film can be changed by increasing the frequency of the modification step. Specifically, the concentration of carbon (C) can be reduced by increasing the frequency of the modification step. In other words, the frequency of the second step (modification step) may be selected according to a desired composition ratio of an insulation film to be formed. Stated differently, the number X of cycles executed in the first step relative to the second step performed each time may be selected according to a desired composition ratio of an insulation film to be formed.

As presented in FIG. 12 by comparing “X=4” and “X=1,” the film density can be changed by increasing the frequency of the modification step. Specifically, the film density can be increased by increasing the frequency of the modification step. In other words, the frequency of the second step (modification step) may be selected according to a desired density of an insulation film to be formed. Stated differently, the number X of cycles executed in the first step relative to the second step performed each time may be selected according to a desired density of an insulation film to be formed.

As presented in FIG. 13 by comparing “X=4” and “X=1,” wet etching resistance can be changed by increasing the frequency of the modification step. Specifically, the wet etching resistance can be improved by increasing the frequency of the modification step. In other words, the frequency of the second step (modification step) may be selected according to desired wet etching resistance of an insulation film to be formed. Stated differently, the number X of cycles executed in the first step relative to the second step performed each time may be selected according to desired wet etching resistance of an insulation film to be formed.

As presented in FIG. 14 by comparing “X=4” and “X=1,” a dielectric constant can be changed by increasing the frequency of the modification step. Specifically, the dielectric constant can be increased by increasing the frequency of the modification step. In other words, the frequency of the second step (modification step) may be selected according to a desired dielectric constant of an insulation film to be formed. Stated differently, the number X of cycles executed in the first step relative to the second step performed each time may be selected according to a desired dielectric constant of an insulation film to be formed.

As presented in FIG. 12 by comparing “X1=1, X2=4” and “X1=1, X2=1,” the composition ratio of the insulation film can be changed by increasing the frequency of the modification step. Specifically, the concentration of carbon (C) can be reduced by increasing the frequency of the modification step. In other words, the frequency of the second step (modification step) may be selected according to a desired composition ratio of an insulation film to be formed. Stated differently, the number X1 of cycles executed and the number X2 of cycles executed in the first step relative to the second step performed each time may be selected according to a desired composition ratio of an insulation film to be formed.

As presented in FIG. 12 by comparing “X1=1, X2=4” and “X1=1, X2=1,” the film density can be changed by increasing the frequency of the modification step. Specifically, the film density can be increased by increasing the frequency of the modification step. In other words, the frequency of the second step (modification step) may be selected according to a desired density of an insulation film to be formed. Stated differently, the number X1 of cycles executed and the number X2 of cycles executed in the first step relative to the second step performed each time may be selected according to a desired density of an insulation film to be formed.

As presented in FIG. 13 by comparing “X1=1, X2=4” and “X1=1, X2=1,” wet etching resistance can be changed by increasing the frequency of the modification step. Specifically, the wet etching resistance can be improved by increasing the frequency of the modification step. In other words, the frequency of the second step (modification step) may be selected according to desired wet etching resistance of an insulation film to be formed. Stated differently, the number X1 of cycles executed and the number X2 of cycles executed in the first step relative to the second step performed each time may be selected according to desired wet etching resistance of an insulation film to be formed.

As presented in FIG. 14 by comparing “X1=1, X2=4” and “X1=1, X2=1,” a dielectric constant can be changed by increasing the frequency of the modification step. Specifically, the dielectric constant can be increased by increasing the frequency of the modification step. In other words, the frequency of the second step (modification step) may be selected according to a desired dielectric constant of an insulation film to be formed. Stated differently, the number X1 of cycles executed and the number X2 of cycles executed in the first step relative to the second step performed each time may be selected according to a desired dielectric constant of an insulation film to be formed.

Embodiments of the method of forming the silicon nitride film using the substrate processing apparatus 100 have been described above, but the present disclosure is not limited to the above embodiment. Various embodiments or improvements can be made within the scope of the present disclosure described in the appended claims.

What is claimed is:

1. A substrate processing method comprising:
i) executing a cycle of i-i) supplying a nitrogen-containing gas to a substrate having a recess and i-ii) supplying a raw material gas including silicon and carbon to the substrate, the cycle being executed one or more times to form a film including at least silicon, carbon, and nitrogen, and i-i) and i-ii) being performed in the order as mentioned; and
ii) exposing the substrate on which the film is formed in i) to plasma of a hydrogen-containing gas to modify the film.

2. The substrate processing method according to claim 1,
wherein a set of i) and ii) is repeated one or more times.

3. The substrate processing method according to claim 1,
wherein i) further includes, after executing the cycle of i-i) and i-ii) one or more times in the order as mentioned, i-iii) supplying an oxygen-containing gas to the substrate.

4. The substrate processing method according to claim 3,
wherein i) includes repeating a set of
the cycle of executing the cycle of i-i) and i-ii) one or more times in the order as mentioned, and i-iii)
one or more times.

5. The substrate processing method according to claim 1,
wherein pressure in ii) is lower than pressure in i).

6. The substrate processing method according to claim 1,
wherein the nitrogen-containing gas is at least one selected from the group consisting of NH₃, N₂H₂, N₂H₄, and an organic hydrazine compound.

7. The substrate processing method according to claim 3,
wherein the oxygen-containing gas is at least one selected from the group consisting of H₂O, H₂O₂, D₂O, O₂, O₃, and alcohol.

8. The substrate processing method according to claim 1,
wherein the raw material gas is at least one selected from the group consisting of 1,1,3,3-tetrachloro-1,3-disilacyclobutane represented by C₂H₄Cl₄Si₂, 1,1,3,3-tetrachloro-1,3-disilapropane represented by CH₄Cl₄Si₂, and 1,1,1,3,3,3-hexachloro-2-methyl-1,3-disilapropane represented by C₂H₄Cl₆Si₂.

9. The substrate processing method according to claim 1,
wherein ii) includes supplying an inert gas together with the hydrogen-containing gas to the substrate.

10. The substrate processing method according to claim 9,
wherein i) includes supplying the inert gas to the substrate together with the nitrogen-containing gas or the raw material gas, and
a flow rate of the inert gas in ii) is greater than a flow rate of the inert gas in i).

11. The substrate processing method according to claim 1,
wherein the hydrogen-containing gas is a H₂ gas.

12. The substrate processing method according to claim 9,
wherein the inert gas is selected from the group consisting of Ar, N₂, and He.

13. The substrate processing method according to claim 1,
wherein the film is a SiCN film or a SiOCN film.

14. The substrate processing method according to claim 1,
wherein a number of times the cycle executed in i) relative to ii) is selected based on a composition ratio of the film.

15. The substrate processing method according to claim 1,
wherein a number of times the cycle executed in i) relative to ii) is selected based on etching resistance of the film.

16. The substrate processing method according to claim 1,
wherein a number of times the cycle executed in i) relative to ii) is selected based on a dielectric constant of the film.
